(19) United States
(12) Patent Application Publication
(10) Pub. No.: US 2023/0036175 A1
(43) Pub. Date: Feb. 2, 2023

(54) BLOCK COPOLYMER SELF-ALIGNMENT ON ISOLATED CHEMICAL STRIPES

(71) Applicants: Wisconsin Alumni Research Foundation, Madison, WI (US); The University of Chicago, Chicago, IL (US)

(72) Inventors: Michael Arnold, Middleton, WI (US); Robert Jacobberger, Madison, WI (US); Paul F. Nealey, Chicago, IL (US); Shisheng Xiong, Darien, IL (US); Tzu-Hsuan Chang, Madison, WI (US); Zhenqiang Ma, Middleton, WI (US)

(21) Appl. No.: 17/757,887

(22) PCT Filed: Dec. 22, 2020
(86) PCT No.: PCT/US2020/066693

§ 371 Date: Jun. 22, 2022

Related U.S. Application Data
(60) Provisional application No. 62/953,387, filed on Dec. 24, 2019.

(51) Int. Cl. C09D 153/00; G03F 7/11; C08L 53/00

(52) U.S. Cl. CPC C09D 153/00; G03F 7/11; C08L 53/00; H01L 21/0271

(57) ABSTRACT

Methods of spatially directing the orientation and placement of multiple block copolymer (BCP) domains on isolated regions of a substrate are described. The methods involve epitaxially directing the assembly of BCP domains using spatial boundaries between regions with different surface composition, formed at the edges of isolated chemical regions on a background chemistry. Multiple vertical domains of BCP order on the isolated region, self-aligned in a direction parallel to edges of the isolated region. In some embodiments, vertical domains order on multiple isolated regions of a first chemistry of a chemical contrast pattern with horizontal domains on the regions of a second (background) chemistry of the chemical contrast pattern. Also provided herein are compositions resulting from the methods.

### RELATED APPLICATIONS

A PCT Request Form is filed concurrently with this specification as part of the present application. Each application that the present application claims benefit of or priority to as identified in the concurrently filed PCT Request Form is incorporated by reference herein in its entirety and for all purposes.

### STATEMENT OF GOVERNMENTAL SUPPORT

This invention was made with government support under DE-SC0016007 awarded by the US Department of Energy. The government has certain rights in the invention.

### BACKGROUND

Block copolymers (BCPs) can assemble into large-scale, dense, and regular nanoscale patterns, making BCP assembly a potential candidate for nanolithography. Directed self-assembly (DSA) of BCPs can be used to control BCP domain orientation and placement on substrate for nanopatterning applications.

### SUMMARY

One aspect of the disclosure relates to a composition including: a chemical contrast pattern, the chemical contrast pattern having a first region of a first chemistry on a background of a second chemistry; and a microphase-separated block copolymer material overlying the chemical contrast pattern, wherein the first chemistry is preferential to a first block of the block copolymer material and the second chemistry is preferential to a second block of the block copolymer material, and wherein at least three domains of the microphase-separated block copolymer material are oriented vertically to and aligned over the first region.

In some embodiments, the first chemistry is a non-two-dimensional material. In some such embodiments, the first chemistry includes a polymer brush or a self-assembled monolayer. In some such embodiments, the first chemistry is selected from a photoresist, poly(methyl methacrylate), polyimide, poly(dimethyl glutarimide), benzocyclobutene, spin-on carbon, amorphous carbon, and silicon nitride, titanium nitride.

In some embodiments, the first chemistry is selected from the group consisting of polymers, organic small molecules, self-assembled monolayers, non-graphene carbon, and metal nitrides. In some such embodiments, the first chemistry is selected from a photoresist, poly(methyl methacrylate), polyimide, poly(dimethyl glutarimide), benzocyclobutene, spin-on carbon, amorphous carbon, silicon nitride, titanium nitride, zirconium nitride, hafnium nitride, vanadium nitride, niobium nitride, tantalum nitride, molybdenum nitride, and tungsten nitride. In some such embodiments, the first chemistry is a self-assembled monolayer having an alkane, thiol, fluoro, silane, or hydroxy head group. Examples of self-assembled monolayers include monolayers of octadecyltrichlorosilane, hexamethyldisilazane, and poly(ethylene glycol).

In some embodiments, the first chemistry includes closed bonds only in one-dimension. In some embodiments, the first chemistry includes a three-dimensional bonding network.

In some embodiments, the second chemistry includes one of a group IV semiconductor, a group III-V semiconductor, and a metal.

In some embodiments, the block copolymer material includes a copolymer of a polymer A and a polymer B, and wherein domains of the polymer B are at the edge of each of the first region.

In some embodiments, there are at least 5 vertical domains of the block copolymer material oriented vertically to and aligned over the first region.

In some embodiments, the first region is an isolated stripe.

In some embodiments, the first region has an irregular shape. In some such embodiments, the irregular shape includes a T-junction, a jog, or an angle.

In some embodiments, the block copolymer material consists essentially of a block copolymer.

In some embodiments, horizontal domains of the block copolymer material are over the background.

In some embodiments, the domains are less than 10 nm wide.

In some embodiments, the chemical contrast pattern includes stripes that are at least 80 nm wide.

In some embodiments, the block copolymer material includes an A-B diblock copolymer or A-B-A triblock copolymer.

Another aspect of the disclosure relates to a composition including: a chemical contrast pattern, the chemical contrast pattern having one or more regions of a first chemistry on a background of a second chemistry, wherein at least one of the one or more regions has an irregular shape; and a microphase-separated block copolymer material overlying the chemical contrast pattern, wherein the first chemistry is preferential to a first block of the block copolymer material and the second chemistry is preferential to a second block of the block copolymer material, and wherein a plurality of domains of the microphase-separated block copolymer material are oriented vertically to and aligned over each of the one or more regions of the first chemistry.

In some embodiments, the irregular shape includes a T-junction, a jog, or an angle.

In some embodiments, the block copolymer material consists essentially of a block copolymer.

In some embodiments, the block copolymer material does not include a homopolymer or other diluent.

In some embodiments, wherein the block copolymer material includes an additive. In some such embodiments, the additive is selected from a homopolymer, an ionic liquid, a nanoparticle, and a salt.

In some embodiments, the first chemistry is graphene.

In some embodiments, the first chemistry is selected from the group consisting of polymers, organic small molecules, self-assembled monolayers, non-graphene carbon, and metal nitrides.

In some embodiments, the second chemistry includes one of a group IV semiconductor, a group III-V semiconductor, and a metal.

In some embodiments, the second chemistry is germanium.

In some embodiments, the smallest dimension of the one or more regions is at least 80 nm.

Another aspect of the disclosure relates to a method including: having one or more regions of a first chemistry on a background of a second chemistry; and coating the chemical contrast pattern with a material including a block copolymer (BCP) having a length scale Lo, wherein the first region has a smallest dimension that is at least 2.5 L₀; and inducing assembly of the BCP to form a thin film including a microphase-separated BCP material overlying the chemical contrast pattern, wherein at least three domains of the microphase-separated BCP are oriented vertically to and aligned over the one or more regions of the first chemistry.

Another aspect of the disclosure relates to a composition including: a chemical contrast pattern, the chemical contrast pattern having a first region of a first chemistry on a background of a second chemistry; and a microphase-separated block copolymer material overlying the chemical contrast pattern, wherein the first chemistry is preferential to a first block of the block copolymer material and the second chemistry is preferential to a second block of the block copolymer material, and wherein one or more domains of the microphase-separated block copolymer material are oriented vertically to and aligned over the first region and wherein horizontal domains are over the background region.

Another aspect of the disclosure relates to a composition including a line-array superlattice including a plurality of arrays of vertical lamellae of a microphase-separated A-b-B block copolymer separated by horizontal lamellae of the microphase-separated block copolymer; wherein the width of each array is nL₀/2, where L₀ is the bulk lattice constant of the A-b-B block copolymer and n is an integer.

Another aspect of the disclosure relates to a composition including a single B lamella of an A-b-B block copolymer having a width L₀/2 where L₀ is the bulk lattice constant of the A-b-B block copolymer and adjacent to horizontal lamellae of the A-b-B block copolymer on each side.

Yet another aspect of the disclosure relates to a composition including: a line-array, each line including a single B lamella of an A-b-B block copolymer having a width L₀/2, where L₀ is the bulk lattice constant of the A-b-B block copolymer, and adjacent to horizontal lamellae of the A-b-B block copolymer on each side.

These and other aspects of the disclosure are discussed further below with reference to the Figures.

### BRIEF DESCRIPTION OF THE FIGURES

FIG. 1 shows an example of ideal phase behavior of a diblock copolymer.

FIG. 2a shows scanning electron microscopy (SEM) images and corresponding schematic diagrams of assembly of multiple domains of a BCP on isolated regions of a chemical contrast pattern.

FIG. 2b shows schematic diagrams illustrating directed self-assembly (DSA) by graphoepitaxy, chemoepitaxy and boundary directed epitaxy.

FIG. 3 is a plot of density multiplication vs. patterned stripe width for a lamellae-forming triblock copolymer of poly(propylene carbonate) (PPC) and polystyrene (PS), PPC-b-PS-b-PPC (L₀ of 14.5 nm).

FIG. 4 shows examples of schematic diagrams of chemical contrast patterns including irregular shapes and schematic diagrams and SEM images of assembled BCP thin films on the chemical contrast patterns.

FIG. 5 shows examples of schematic diagrams of chemical contrast patterns of isolated ribbons and schematic diagrams and SEM images of assembled BCP thin films on the chemical contrast patterns.

FIG. 6 shows additional examples of schematic diagrams of chemical contrast patterns of various shapes and schematic diagrams and SEM images of assembled BCP thin films on the chemical contrast patterns.

FIG. 7 is schematic diagram showing the evolution of assembly of a BCP film according to the methods described herein.

FIGS. 8a-8c show schematic examples of line arrays formed by boundary directed epitaxy.

FIG. 9 shows SEM images and schematics illustrating the effect of anneal time on assembly by boundary directed epitaxy.

### DETAILED DESCRIPTION

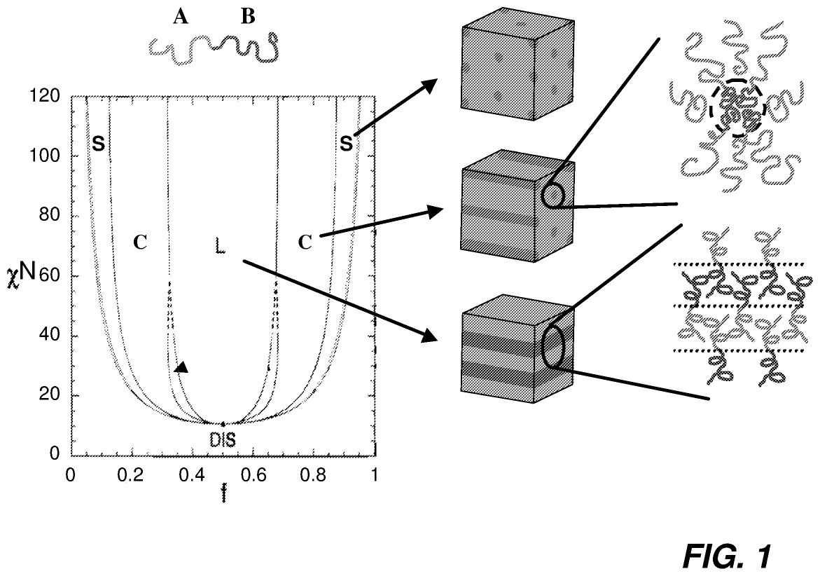

Self-assembling materials spontaneously form structures at length scales of interest in nanotechnology. BCPs are a class of polymers that have two or more polymeric blocks. The structure of diblock copolymer AB, also denoted A-b-B, may correspond, for example, to AAAAAAA-BBBBBBBB, where each A or B represents a monomer. FIG. 1 shows theoretical phase behavior of an A-b-B diblock copolymer. The graph in FIG. 1 shows, χN (where χ is the Flory-Huggins interaction parameter and N is the degree of polymerization) as a function of the volume fraction, f, of a block (A) in a diblock (A-b-B) copolymer. χN is related to the energy of mixing the blocks in a diblock copolymer and is inversely proportional to temperature. FIG. 1 shows that at a particular temperature and volume fraction of A, the diblock copolymers microphase separate into domains of different morphological features (also referred to as microdomains). As indicated in FIG. 1, when the volume fraction of either block is around 0.1, the block copolymer will microphase separate into spherical domains (S), where one block of the copolymer surrounds spheres of the other block. As the volume fraction of either block nears around 0.2-0.3, the blocks separate to form a hexagonal array of cylinders (C), where one block of the copolymer surrounds cylinders of the other block. And when the volume fractions of the blocks are approximately equal, lamellar domains (L) or alternating stripes of the blocks are formed. Representations of the cylindrical and lamellar domains at a molecular level are also shown. Domain size typically ranges from 2 nm or 3 nm to 50 nm. The phase behavior of block copolymers containing more than two types of blocks (e.g., A-b-B-b-C), also results in microphase separation into different domains. The size and shape of the domains in the bulk depend on the overall degree of polymerization, N, the repeat unit length, a, the volume fraction of one of the components, f, and the Flory-Huggins interaction parameter, χ.

A block copolymer material may be characterized by bulk lattice constant or period L₀. For example, a lamellar block copolymer film has a bulk lamellar period or repeat unit, L₀ equal to the width of two stripes. For cylindrical and spherical domain structures, the periodicity L₀ of the bulk domain structures can be characterized by a center-to-center distance between the cylinders or spheres, e.g., in a hexagonal array. While the FIG. 1 shows an example of phase behavior of a diblock copolymer for illustrative purposes, the phase behavior of triblock and higher order block copolymers also can result in microphase separation into different architectures.

Provided herein are methods of spatially directing the orientation and placement of multiple BCP domains on isolated regions of a substrate. The methods involve epitaxially directing the assembly of BCP domains using spatial boundaries between regions with different surface composition, formed at the edges of isolated chemical regions on a background chemistry. Multiple vertical domains of BCP order on the isolated region, self-aligned in a direction parallel to edges of the isolated region. In some embodiments, vertical domains order on multiple isolated regions of a first chemistry of a chemical contrast pattern with horizontal domains on the regions of a second (background) chemistry of the chemical contrast pattern. Also provided herein are compositions resulting from the methods.

Vertical domains are domains that are oriented vertically with respect to an underlying substrate and horizontal domains are domains that are oriented horizontally with respect to the substrate. (Vertical domains are also referred to as perpendicular domains because they are oriented perpendicularly to the substrate and horizontal domains are also referred to as parallel domains because they oriented parallel to the substrate). Vertical domains in a thin film are useful for patterning as the pattern at the substrate-thin film interface is present through the entire thickness of the BCP film and can be accessed from the top of the thin film.

While the description below describes assembly of lamellar domains, using boundaries of chemical contrast patterns to direct the orientation, lateral order, and position of BCP domains may be extended to other morphologies (e.g., cylinders) or more complicated architectures.

According to various embodiments, one or more advantages of the methods and compositions may be realized. In some embodiments, the methods provide directed self-assembly of high resolution features without topographic features or high resolution chemical guiding stripes. In some embodiments, the methods provide well-defined placement of block copolymer domains on patterned regions of various shapes. In some embodiments, nanopatterning may be performed at resolutions higher than that allowed by standard lithographic techniques. In some embodiments, sub-10 nm patterning may be performed using standard lithography to define the chemical contrast pattern and then thermal annealing of a BCP on the chemical contrast pattern.

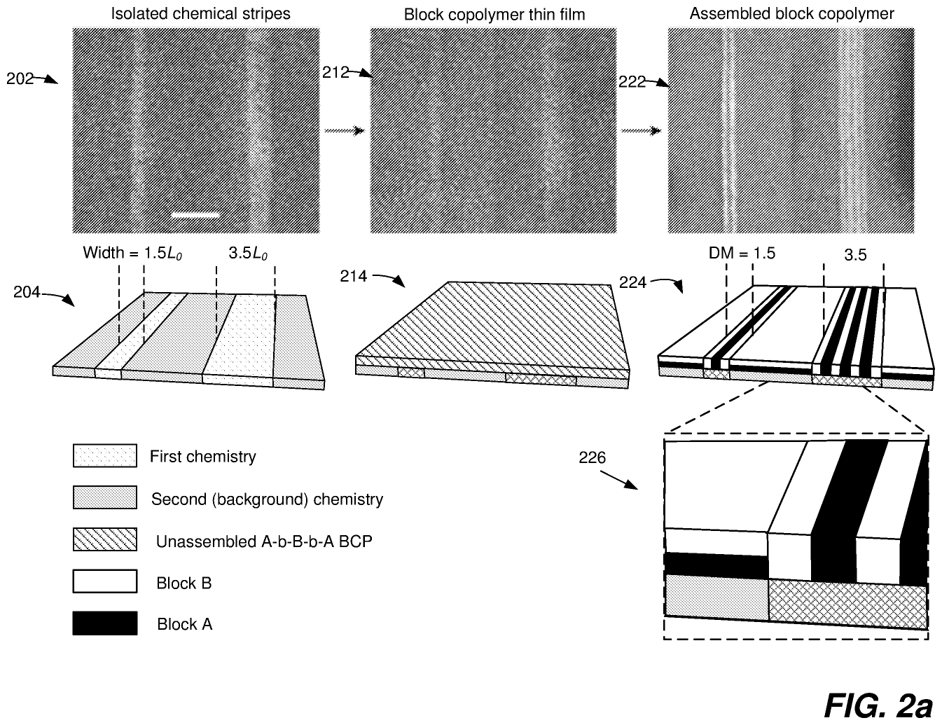

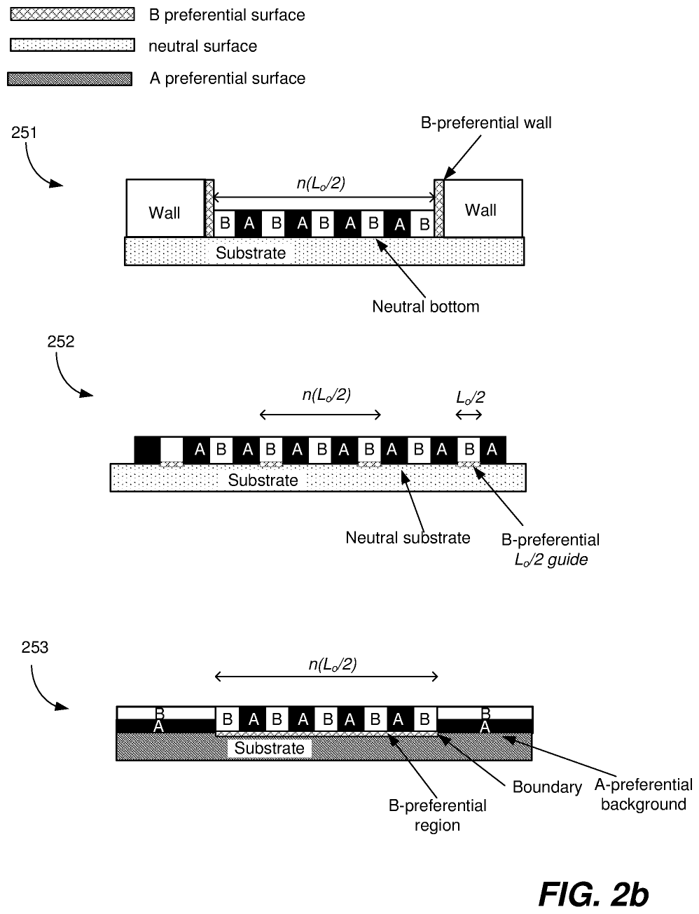

FIG. 2a shows an example of BCP assembly of multiple vertical domains on an isolated region of a chemical contrast pattern. An SEM image 202 of a chemical contrast pattern is shown, with the scale bar being 100 nm. A schematic diagram 204 of the chemical contrast pattern is also shown. The chemical contrast pattern includes regions of a first chemistry on a background of a second chemistry. In the example of FIG. 2a, the chemical contrast pattern includes two isolated stripes (also referred to as ribbons), one having a smallest dimension (width) of 1.5 L₀ and one of 3.5 Lo, where L₀ is the characteristic length scale of the BCP to be assembled.

A SEM image 212 of a thin film of a BCP material deposited on the chemical contrast pattern, prior to assembly, and a corresponding schematic diagram 214 are shown. The film is then thermally annealed so that it undergoes self-assembly, as directed by the underlying chemical contrast pattern. A SEM image 222 of the assembled BCP film is shown, along with corresponding schematic diagram 224 and enlarged view 226 that provides a detailed view of the interface between vertical and horizontal BCP domains at the interface between the first chemistry/background of the chemical contrast pattern. As can be seen in the SEM image at 222, the schematic diagram 224 and enlarged view 226, the BCP assembles into multiple vertical lamellar domains on each isolated stripe.

The process flow shown in FIG. 2a differs significantly from BCP assembly on chemical contrast patterns that have an underlying periodicity such as alternating guiding and background stripes. In such chemical contrast patterns, the guiding stripes have a chemistry that is preferentially wet by one of the blocks of the BCP, while the background is neutral or preferentially wet by the other block. The preferential guiding stripes pin one block to control domain placement and background regions either pin the other block if they are preferential or allow both blocks to wet their surface to achieve density multiplication if they are neutral.

The process flow shown in FIG. 2a also differs significantly from BCP assembly on topographical patterns in DSA by graphoepitaxy.

FIG. 2b compares these methods: at 251, DSA by graphoepitaxy is shown in which walls having a B-preferential surface are spaced n(Lₒ/2) apart to form a trench, where n is an integer. The substrate is neutral. The neutral substrate allows for vertical assembly, with the B-preferential walls guiding the assembly of BCP deposited in the trench. Graphoepitaxy is sensitive to underfilling and overfilling of BCP in the trenches and requires fabrication of topographic structures that interfere with subsequent processing if the structures cannot be removed. At 252, DSA by chemoepitaxy is shown, with periodic B-preferential guiding stripes of Lₒ/2 width on a neutral background directing the assembly of the BCP.

The chemical contrast patterns used for BCP assembly as described herein, by contrast, have multiple isolated regions on a continuous background region. The isolated regions may be preferential to one block of the BCP with the background preferential to another block. This is illustrated in FIG. 2b at 253. The techniques described herein and illustrated in FIG. 2a and at 253 in FIG. 2b may be referred to as “boundary directed epitaxy.” Experiments and simulations demonstrate that chemical contrast at each stripe/substrate boundary nucleates and pins the formation of vertical lamellae along the stripe edges. Vertical lamellae then propagate into the interior of each stripe, resulting in registered vertical line arrays that selectively form on stripes, self-align parallel to the boundaries, and register to wide and incommensurate stripes to multiply the feature density. Horizontal lamellae form on the background; thus, the lamellar orientation is sharply modulated at the stripe edges.

Directed self-assembly using conventional chemical contrast patterns requires the formation of narrow guiding features that have widths of 0.5-1.5 times the BCP domain spacing (L₀), where a width of 0.5 L₀ is ideal. Therefore, to achieve BCP assemblies with sub-10 nm domains via conventional chemoepitaxy, it is advantageous to use sub-10 nm guiding features; however, such features are difficult to fabricate.

In contrast, in boundary-directed epitaxy as described herein, these requirements are circumvented by directing assembly using spatial boundaries between planar, low-resolution regions on a surface with different composition. Pairs of boundaries are formed at the edges of isolated stripes on a background substrate. Vertical lamellae nucleate at and are pinned by the chemical contrast at each stripe/substrate boundary, align parallel to the boundaries, selectively propagate from the boundaries into stripe interiors (whereas horizontal lamellae form on the background), and register to wide stripes to multiply the feature density. Numerous vertical lamellae can assemble on a single stripe to produce periodic line arrays even on stripes much wider than L₀ (e.g., stripe width of 15.5 L0), thereby multiplying the feature density compared to the stripe width.

The number of vertically-oriented lamellae is controlled by ribbon width and the same block borders both long ribbon edges, resulting in odd numbers of lines and density multiplication of (2n+1)/2 where n is a positive integer. For example, ribbon widths of 1.5, 2.5, 3.5, and 4.5 L₀ result in 3, 5, 7, and 9 lines, respectively. Thus the number of alternating A-B domains can be controlled by appropriately sizing a dimension of the isolated region of the chemical contrast pattern.

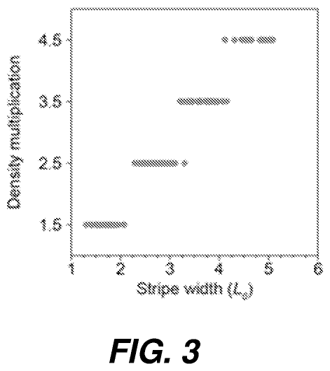

In some embodiments, the self-alignment and density multiplication shown in FIG. 2a can be achieved on incommensurate patterns in which ribbon width does not match ((2n+1)/2)L₀. This is shown in FIG. 3, which is a plot of density multiplication vs. stripe width for a lamellae-forming triblock copolymer of poly(propylene carbonate) (PPC) and polystyrene (PS), PPC-b-PS-b-PPC (L₀ of 12.8 nm). For example, density multiplication of 1.5 and 2.5 are typically observed on ribbon widths of roughly 1.25-2.25 L₀ and 2.25-3.25 L₀, respectively. Thus in certain embodiments, BCP domains can form features up to roughly 10% smaller or 50% larger than Lo, when using triblock BCPs (e.g., A-B-A).

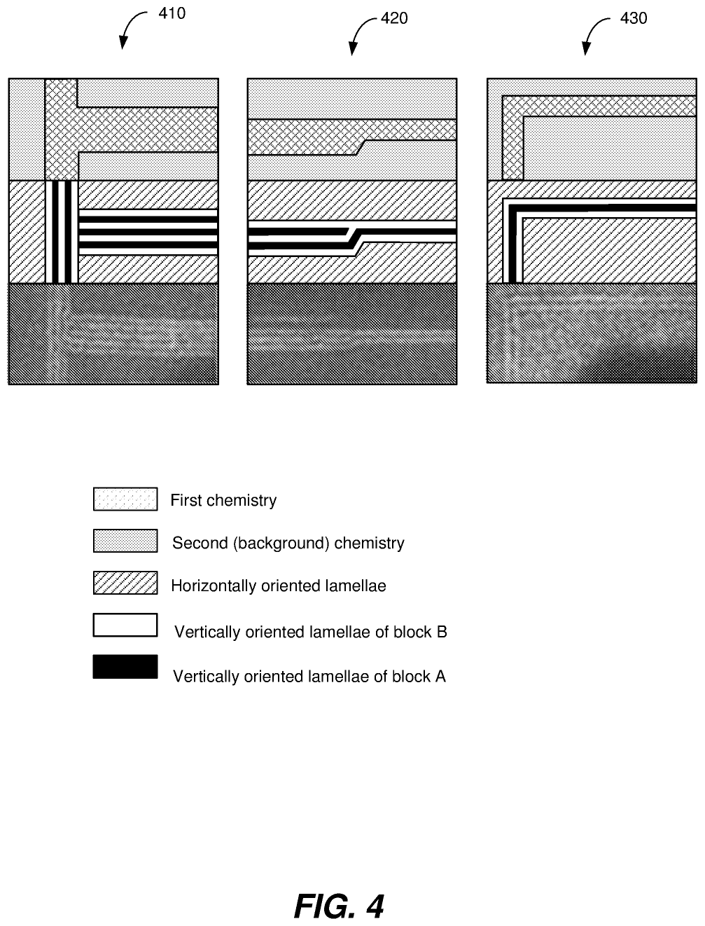

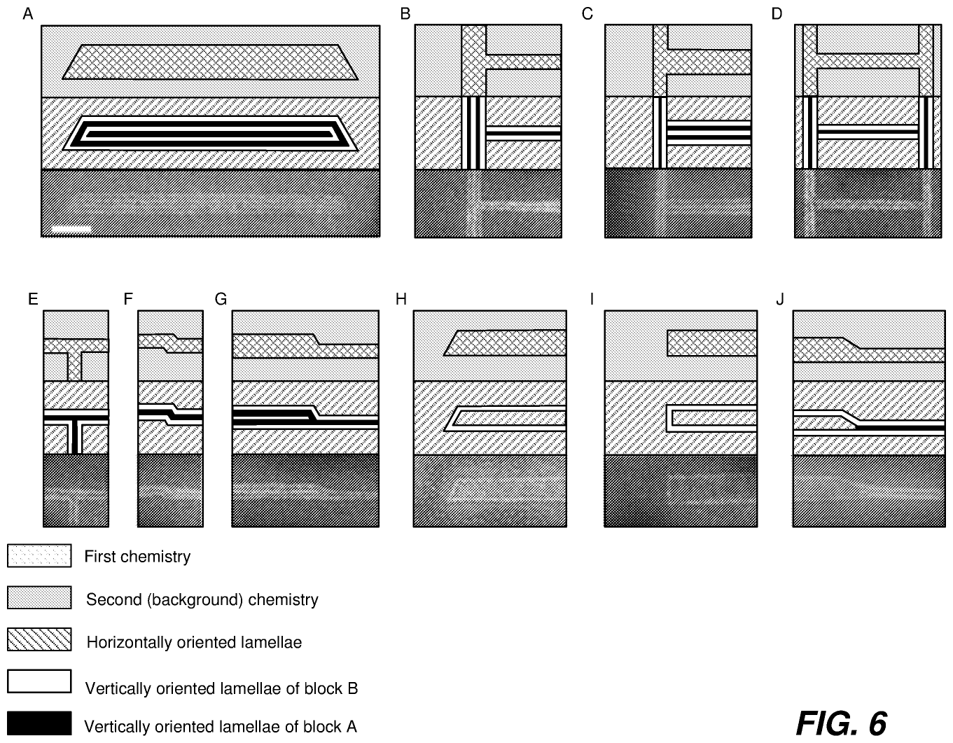

Assembly on stripes with high incommensurability also enables production of more complex BCP patterns, including those useful for fabrication of integrated circuits (ICs). In particular, the chemical contrast pattern may have isolated regions of arbitrary shapes, including irregular shapes. As used herein, the term irregular shape refers to any shape other than a line of whose width varies by no more than 0.2 L₀. Examples of irregular shapes that are useful for IC fabrication include junctions including T-junctions, jogs, and bends including 60°, 90°, and 120° bends. FIG. 4 shows examples of a T-junction (at 410), a jog (at 420) and a 90° bend (at 430). The top row includes schematic diagrams of the chemical contrast pattern, the middle row includes schematic diagrams of the assembled film on the chemical contrast pattern, and the bottom row includes SEM images of the assembled films. Junctions are examples of irregular shapes that include two intersecting lines. The lines may intersect at any angle with T-junctions referring to substantially perpendicular lines, H-junctions referring to a line intersecting two spaced apart perpendicular lines, etc. Jogs are examples of irregular shapes in which one or both of the long edges of a line is or are displaced. In some embodiments, a jog may widen a line to accommodate at least one additional pair of alternating BCP (A-B) domains. As such, the line may widen at least 0.9 L₀, for example. In other embodiments, a line may maintain its width before and after the jog, such that the number of alternating domains remains the same. As example of the latter is shown in FIG. 6, below. Bends are examples of irregular shapes in which a line bends. In some embodiments, the methods involve forming irregular shapes such as T-junctions in a BCP thin film without stabilization by homopolymers, other diluents, or nanoparticles.

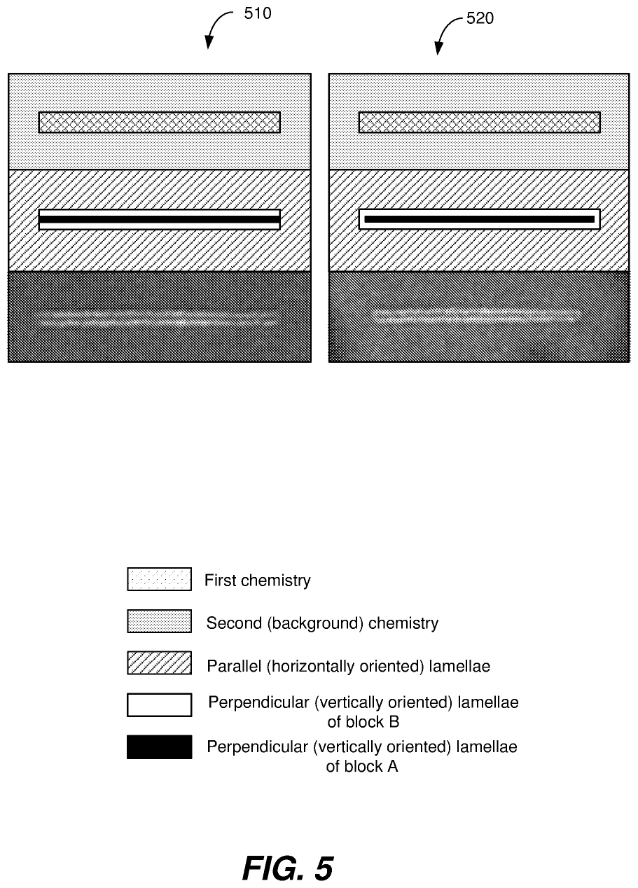

In addition to the irregular shapes described above, the chemical contrast pattern may include isolated stripes (also referred to as isolated ribbons) of uniform width as shown in FIG. 2. In such cases, the block that forms the outer edges along the length of the lines may or may not bend to form the outer short edges. This is shown in FIG. 5, which shows schematic diagrams of chemical contrast patterns and schematic diagrams and SEM images of assembled BCP thin films on the chemical contrast patterns. The top row shows chemical contrast patterns of an isolated ribbon. PPC-b-PS-b-PPC (L₀ of 12.8 nm) is assembled to form isolated arrays of three lines. At 520, vertical PS lamella bends to directly border both the long and short ribbon edges, whereas at 510, vertical lamellae that are self-aligned to the long ribbon edges extend the entire ribbon length. The latter occurs more often when width is 1.5 L₀.

FIG. 6 shows additional examples of schematic diagrams of chemical contrast patterns and schematic diagrams and SEM images of assembled BCP thin films on the chemical contrast patterns. The patterns include an isolated line array with seven vertical lamellae (a);

T-junctions with different numbers of vertical lamellae (b-d); three vertical lamellae splitting into two mirrored 90° bends rather than forming T-junctions (e); a jog with three vertical lamellae (0; a jog similar to that at 520 in FIG. 5, except only the outermost PS line jogs when ribbon width changes (g); 60 and 120° bends with a single vertical lamella (h); 90° bends with a single vertical lamella (i), and two continuous vertical lamellae where their separation distance is varied, which is similar to the gate layer for NAND2 or NOR2 layout in integrated circuits. In some embodiments, meta-stable or equilibrium structures may form. For example, a T-junction could be an equilibrium structure and a mirrored bend a meta-stable structure. Forming mirrored bends or T-junctions may be influenced by controlling stripe dimensions, annealing temperature, or annealing time.

The patterns in (h), (i), and (j) may be produced by partially assembling the BCP by annealing for relatively short time so that vertical PS lamellae are only formed at the boundary between the first chemistry and the background substrate.

In certain embodiments, vertical domains form over the isolated regions of the chemical contrast pattern while horizontal domains form over the background regions. This is shown schematically in FIG. 2a, described above. For lamellae, domains that form parallel to the substrate (i.e., horizontally oriented lamellae) result in only one block wetting the substrate surface, whereas domains that form perpendicular to the substrate (i.e., vertically oriented lamellae) result in different blocks wetting the substrate surface. Vertical domains allow patterning of the underlying substrate. One of the vertical blocks of the block copolymer thin film can be removed, e.g., by an oxygen plasma, thereby creating raised features of the other block. The resulting topographic pattern can be transferred to the underlying substrate using the topographic pattern as an etch mask or to a second substrate using a molding or nanoimprinting process. Pattern transfer techniques such as reactive ion etch and thin film deposition may be employed. In this manner, integrated circuits, information storage media, nanoimprint templates, and the like may be fabricated.

In certain embodiments, after spin-coating, the BCP film has no lateral order on the chemical contrast pattern. Upon annealing, however, vertical lamellae form directly and exclusively along each edge of the isolated regions, effectively self-aligning a single block stripe at the chemical contrast pattern interfaces. These vertical lamellae remain pinned at the interfaces as assembly progresses. In contrast, horizontal lamellae form on the background and, for ribbons wider than 1.5 L₀, also initially form on isolated regions away from their edges.

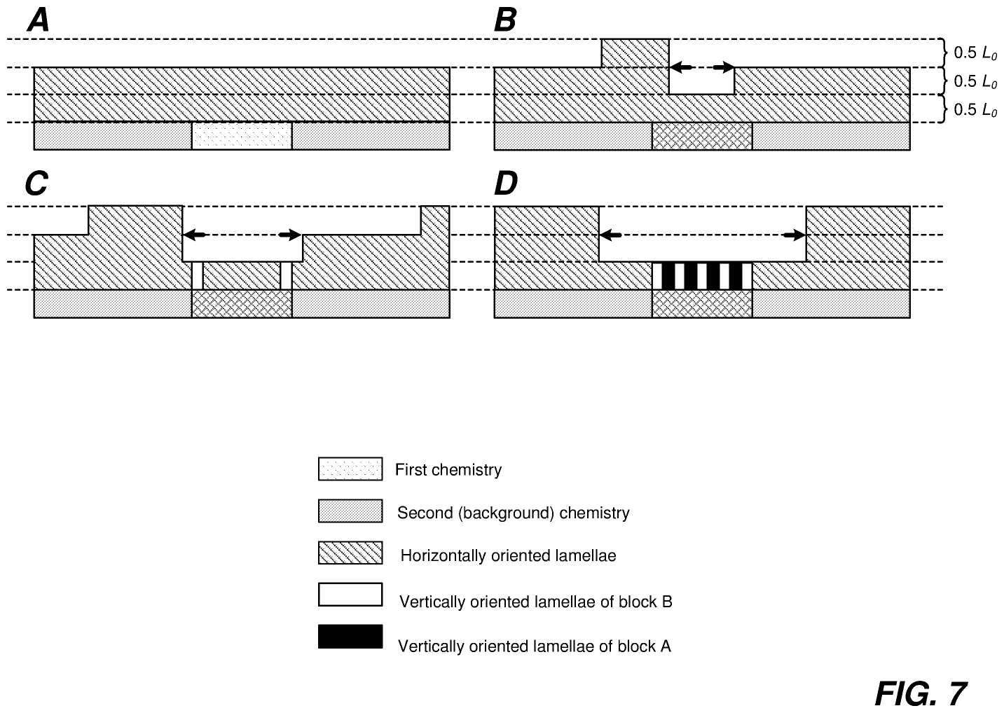

On ribbons or other shapes wider than 1.5 L₀, additional self-aligned vertical lamellae can subsequently form over the interior of isolated regions to achieve density multiplication. As anneal time increases, discontinuous dot-like domains may form in the interior. These discontinuous domains eventually coalesce to form vertical lamellae that align to the previously formed vertical lamellae that are pinned at the chemical contrast interfaces. FIG. 7 is a schematic diagram showing the evolution of assembly, including (A) spin-coating of the BCP film, (B) preferential hole and island formation on a first chemistry and background chemistry, respectively, upon thermal annealing, (C) hole/island interface propagation over ribbon edges and corresponding formation of vertical lamellae at the first chemistry/background chemistry interface, and (D) formation of additional vertical lamellae from ribbon edges to ribbon center.

Assembly is dictated by the chemical contrast interfaces formed at the isolated region edges. As such, self-alignment of vertical lamellae during density multiplication propagates from the edges of the isolated regions to the center, with the assembly kinetics depending on the size. Larger density multiplication can be realized by increasing anneal time. And as described above, assembled thin films that have vertical domains only at the edges of the isolated shapes may be formed by partial assembly using shorter anneal times.

The sharp contrast between vertical and horizontal domains at the interfaces of the chemical contrast pattern occurs for background regions that are preferential to one block of the BCP; neutral backgrounds will result in vertical domains that may self-assemble in an unguided manner to patterns such as fingerprint patterns.

Having the horizontal domains overlie the background regions of the chemical contrast pattern facilitates pattern transfer into the substrate at the desired locations. The presence of vertical domains over the background (for example in a fingerprint pattern) can make it difficult to usefully transfer the patterns in the BCPs that only overlie the isolated regions.

Density multiplication as high as about 15.5 L₀ may be achieved according to various embodiments. The length scale of the BCP and the desired density multiplication determine the size of the patterned regions. For example, if a BCP has an L₀ of 12.8 nm, and a DM of 5.5 is desired (e.g., resulting in 5 or 6 stripes after pattern transfer depending on which block is removed to transfer the pattern), the patterned region could be patterned at a width of 5.5×12.8=70.4 nm wide.

In some embodiments, the patterns resulting after BCP assembly and subsequent pattern transfer have smallest dimensions (e.g., widths) no more than that which optical lithography may be used to produce. Optical lithography may be used to pattern as low as about 70 nm, for example. The patterns may have small spacing (distance between patterned regions), e.g., 5-10 nm or about 0.5 L₀.

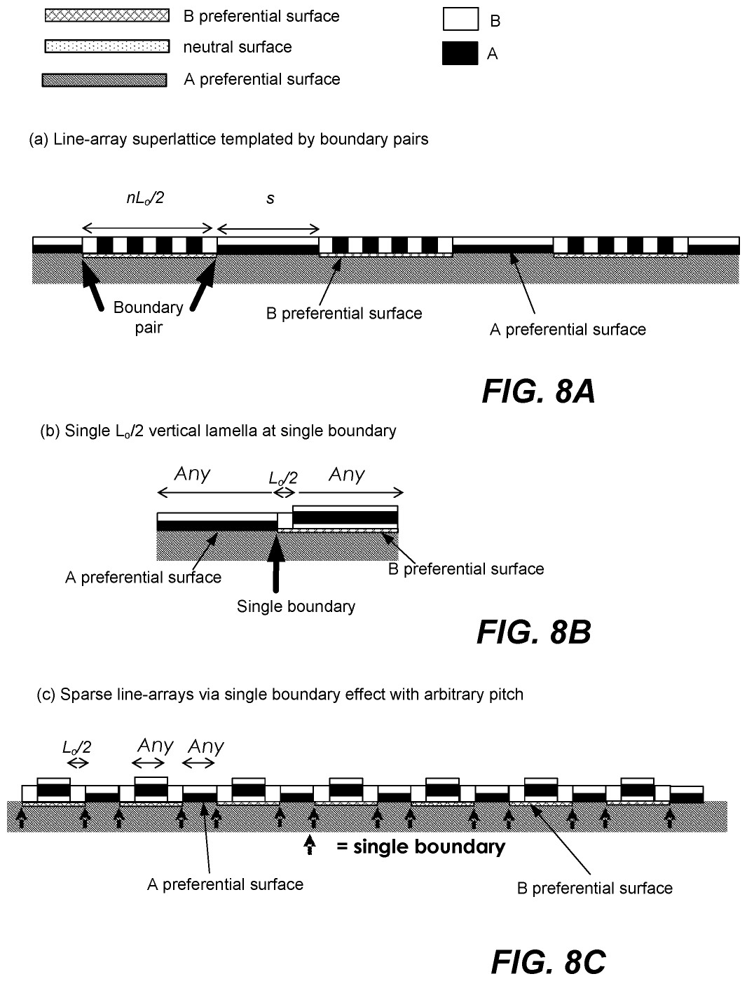

In some embodiments, boundary directed epitaxy is implemented to form a line-array superlattice templated by boundary pairs. This is shown in FIG. 8a, in which isolated stripes of B-preferential regions are patterned close together to form a line-array superlattice, with each region of vertical domains (lines) separated by a region S wide of horizontal domains. S may be as low as L₀/2 and possibly smaller in some embodiments.

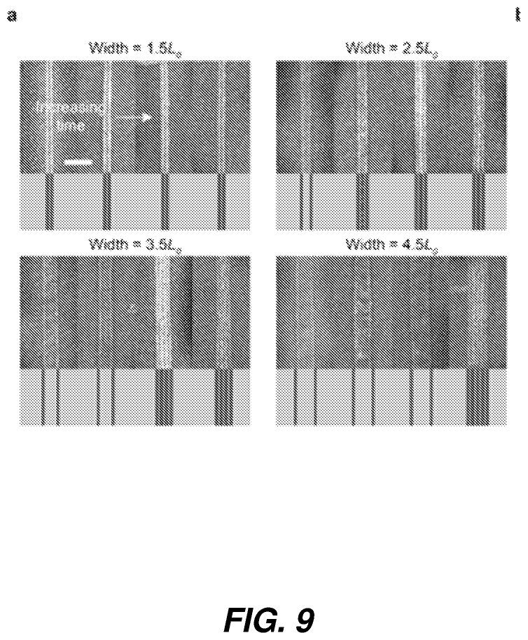

In some embodiments, single boundaries, rather than boundary pairs, are used to direct assembly. FIG. 9 shows at short annealing time that it is possible to template a single lamella at a single boundary. This phenomenon is interesting because a single boundary can be created between two regions of any shape and size. Assembly driven by a single boundary is schematically shown in FIG. 8b. FIG. 8c shows a schematic of single boundaries creating sparse line-arrays at arbitrary pitch. Unlike arrays produced via density multiplication that must adopt the natural period (L₀) of the BCP, line-arrays produced via the single boundary effect can be constructed with pitch that is arbitrary and a non-integer multiple of L₀. Such line-edge arrays could be more defect-free due to the lack of commensurability constraints and limitations imposed by line-width roughness.

FIG. 9 shows SEM images and schematics corresponding to PPC-b-PS-b-PPC (L₀ of 12.8 nm) morphology after assembly at 130° C. for 1, 10, 1440, and 5040 min (left to right) on stripes with width of ˜1.5, 2.5, 3.5, and 4.5 L₀. Vertical PS and PPC lamellae shown as striped lines with horizontal lamellae separating the striped lines in the schematics.

### Block Copolymers (BCPs)

A BCP may be selected based on its characteristic length scale. High χ BCP's have smaller length scales, which may be of interest in applications such as nanolithography for semiconductor devices such as FinFETs, fabrication of cell-based assays, nanoprinting, photovoltaic cells, and surface-conduction electron-emitter displays.

In some embodiments, a BCP having constituent blocks that have similar surface energies is used. For example, poly(propylene carbonate) (PPC) and polystyrene (PS) have similar block surface energies which may facilitate vertical lamellae to form and extend through the thickness of a thin film without solvent annealing or the use of topcoats. BCPs including PPC and PS also have high χ's and may be useful for small features.

In some embodiments, a block copolymer can be chosen based on a desired chemical or functional characteristic of one or more components blocks, such as etch selectivity in a particular etchant. In addition to PS and PPC, examples of components of BCPs include polymethylmethacrylate (PMMA), polyethylene oxide (PEO), polydimethylsiloxane (PDMS), poly-2-vinylpyridine (P2PV), poly-4-vinylpyridine (P4VP), polyacrylate, polypropylene oxide (PPO), polyethylene, polyacrylonitrile (PAN), polylactide, polyacrylic acid (PAA), and polyisoprene.

### Chemical Contrast Pattern Materials

The preferentiality of both the isolated regions and background to different polymer blocks of the BCP is an important aspect of the assembly in the methods described herein. For example, BCP epitaxy is not observed if the background is neutral to both blocks. Such a scenario is experimentally demonstrated by comparing PS-b-PPC assembly on graphene stripes on germanium (Ge) with PS-b-PMMA assembly on the same contrast pattern. The former results in self-alignment as shown in FIG. 2a, as graphene is preferentially wet by PS and Ge by PPC. However, Ge is neutral to PS and PMMA, resulting in assembly of small disordered grains of vertical lamellae on Ge and horizontal lamellae on graphene.

The complementary scenario of isolated neutral stripes on a preferential background results in formation of horizontal lamellae on the background and vertical lamellae on the stripes. However, the vertical lamellae fail to align along or register to the stripe edges. These results indicate that assembly is only realized when there is suitable chemical contrast at the stripe/substrate boundary.

Thus, the materials for the chemical contrast pattern including isolated regions (of a first chemistry) and the background (of a second chemistry) may be selected based on the BCP, with each chemistry preferential to a different polymer of the BCP. In some embodiments, the isolated region itself is ‘weakly’ preferential to one of the blocks of the BCP, e.g., in an A-B or A-B-A block copolymer, to block B. If it is too preferential to block A, horizontal domains (e.g., horizontal lamellae) may form over all or at least the interior of the isolated regions. If it is more neutral, then self-alignment will not occur.

The background may be strongly or weakly preferential to one of the blocks of the BCP, e.g., in the A-B or A-B-A block copolymer, to block A. This will induce horizontal orientation of the BCP as described above.

In some embodiments, the chemical contrast pattern includes a first region of a first chemistry on a background of a second chemistry, where the first chemistry is preferential to a first block of a block copolymer and the second chemistry is preferential to a second block of the block copolymer, the second chemistry being more preferential to the second block than the first chemistry is to the first block.

Preference between a block of a block copolymer and a surface chemistry can be determined from the block-surface interfacial energy as reported in literature or experimentally determined.

Examples of background chemistries that may be used with a variety of BCPs include group IV semiconductors, group III-V semiconductors, and metals. In some embodiments, germanium may be used.

Examples of isolated region chemistries that may be used with these background regions include polymers, organic small molecules (organic molecules having a number average molecular weight of 900 Daltons), self-assembled monolayers, non-graphene carbon, and metal nitrides. Polymers may be in the form of polymer brushes that are grafted to the substrate surface.

Specific examples include photoresist, poly(methyl methacrylate), polyimide, poly(dimethyl glutarimide), benzocyclobutene, spin-on carbon, amorphous carbon, and metal nitrides. Examples of metal nitrides include silicon nitride, titanium nitride, zirconium nitride, hafnium nitride, vanadium nitride, niobium nitride, tantalum nitride, molybdenum nitride, and tungsten nitride.

Self-assembled monolayers may have an alkane, aryl, thiol, fluoro, hydroxy, ionic, or non-ionic head group in some embodiments. In some embodiments, the self-assembled monolayer includes octadecyltrichlorosilane, hexamethyldisilazane, and poly(ethylene glycol).

In some embodiments, the isolated region is patterned with a two-dimensional layer. These include layers that are a single atom thick (like graphene) as well as layers that may have a thickness greater than 1 atom (like molybdenum disulfide), but with a thickness of no more than a few nanometers. The two-dimensional layers are generally layers of a material that have closed bonds in two dimensions. The two-dimensional layers are typically two-dimensional crystals. The chemical patterns may be formed in a monolayer or in multiple layers of a two-dimensional material. The layers may be characterized as having a lack of topography as compared to polymer brush layers and mats and self-assembled monolayers. Topography refers to both the step height from a two-dimensional material in an isolated region to the background, as well as the surface roughness of the two-dimensional material. For monolayers of two-dimensional materials, the step height corresponds to the size of one atom or other unit of the material. The two-dimensional materials may be atomically smooth. Graphane, graphene, graphyne, germanane, germanene, borophene, silicene, stanene, phosphorene, boron nitride (BN), carbon nitride, silicon carbide, metals such as palladium and rhodium, and metal-containing compounds including nickel HITP and transition metal dichalcogenides such as tungsten diselenide (WSe₂) and molybdenum disulfide (MoS₂) may be used.

Non-two-dimensional materials may also be used. These include materials that have closed bonds in only one dimension (e.g., polymer brushes) as well as three-dimensional bonding networks such as self-assembled monolayers and mats. In some embodiments, both the background chemistry and the isolated region chemistry may have about the same thickness to minimize step height.

### Method

The pattern may be formed by any appropriate technique, including photolithography, 193 nm immersion lithography, and extreme ultraviolet (EUV) technology. Once formed, a solution including the BCP is spin-coated on the pattern. In addition to a solvent and the BCP, one or more additional components may be included in the solution including nanoparticles, diluents such as homopolymers, ionic liquids, or salts. These may be microphase-separated with one or more of the domains of the assembled BCP, and may impart some functionality (e.g., conductive nanoparticles to impart ionic or electronic conductivity, or an etch resistant material to increase etch selectivity) or widen a process window (e.g., a diluent to increase stretchability or compressability of the BCP).

After spin-coating, the BCP is induced to assemble. Typically this involves thermal anneal, though other methods including solvent anneal may be used. In some embodiments, assembly using thermal anneal may be performed much more quickly than for other types of DSA by chemical epitaxy in which assembly may take tens of hours. For a given anneal time, larger density multiplication can be obtained by increasing temperature. Similarly, to realize a given density multiplication, anneal time can be reduced by increasing temperature. For example, density multiplication of 3.5 was achieved after annealing for roughly 24 h, 10 min, 2.5 min, and 30 s at 130, 160, 175, and 190° C., respectively, for PPC-PS-PPC (L0=12.8 nm). Self-alignment can be disrupted, however, if anneal time is too long or anneal temperature is too high, which is likely due to degradation or dewetting of the BCP film. Assembly kinetics roughly exhibit an Arrhenius dependence, indicating self-alignment is thermally activated and an energy barrier associated with some rate-limiting process (e.g., BCP diffusion) is overcome to achieve density multiplication.

### EXAMPLES

The examples herein use PPC-b-PS-b-PPC and PS-b-PPC block copolymers on graphene patterned on a germanium background. Ge(001) substrates (Wafer World, resistivity >50 Ω-cm) are loaded into a horizontal furnace with a quartz tube inner diameter of 34 mm. The system is evacuated to <10⁻² torr and then refilled to atmospheric pressure with a flow of Ar and H₂. After annealing the substrates at 910° C., CH₄ is introduced to begin graphene growth. The furnace is slid away from the growth zone to terminate growth while maintaining the same atmosphere used during graphene synthesis. After growth of graphene stripes on Ge via CVD, a BCP film with thickness of ˜L₀ is spin-coated onto the surface. The BCP film is thermally annealed on a hotplate in an inert environment (1 atm of N₂ with <1 ppm H₂O and <1 ppm O₂) to microsegregate the BCP domains. Assembly is achieved by thermal annealing, without relatively complex solvent annealing or topcoats. Samples are imaged with SEM (Zeiss LEO 1530) using an in-lens detector.

1. A composition comprising:
a chemical contrast pattern, the chemical contrast pattern having a first region of a first chemistry on a background of a second chemistry; and
a microphase-separated block copolymer material overlying the chemical contrast pattern, wherein the first chemistry is preferential to a first block of the block copolymer material and the second chemistry is preferential to a second block of the block copolymer material, and wherein at least three domains of the microphase-separated block copolymer material are oriented vertically to and aligned over the first region, wherein the first chemistry is a non-two-dimensional material.

2. The composition of claim 1, wherein the first chemistry comprises a polymer brush or a self-assembled monolayer.

3. The composition of claim 1, wherein the first chemistry is selected from a photoresist, poly(methyl methacrylate), polyimide, poly(dimethyl glutarimide), benzocyclobutene, spin-on carbon, amorphous carbon, and silicon nitride, titanium nitride.

4. A composition comprising:
a chemical contrast pattern, the chemical contrast pattern having a first region of a first chemistry on a background of a second chemistry; and
a microphase-separated block copolymer material overlying the chemical contrast pattern, wherein the first chemistry is preferential to a first block of the block copolymer material and the second chemistry is preferential to a second block of the block copolymer material, and wherein at least three domains of the microphase-separated block copolymer material are oriented vertically to and aligned over the first region, wherein the first chemistry is selected from the group consisting of polymers, organic small molecules, self-assembled monolayers, non-graphene carbon, and metal nitrides.

5. The composition of claim 4, wherein the first chemistry is selected from a photoresist, poly(methyl methacrylate), polyimide, poly(dimethyl glutarimide), benzocyclobutene, spin-on carbon, amorphous carbon, silicon nitride, titanium nitride, zirconium nitride, hafnium nitride, vanadium nitride, niobium nitride, tantalum nitride, molybdenum nitride, and tungsten nitride.

6. The composition of claim 4, wherein the first chemistry is a self-assembled monolayer having an alkane, thiol, fluoro, silane, or hydroxy head group.

7. The composition of claim 4, wherein the self-assembled monolayer comprises one of octadecyltrichlorosilane, hexamethyldisilazane, and poly(ethylene glycol).

8. A composition comprising:
a chemical contrast pattern, the chemical contrast pattern having a first region of a first chemistry on a background of a second chemistry; and
a microphase-separated block copolymer material overlying the chemical contrast pattern, wherein the first chemistry is preferential to a first block of the block copolymer material and the second chemistry is preferential to a second block of the block copolymer material, and wherein at least three domains of the microphase-separated block copolymer material are oriented vertically to and aligned over the first region, wherein the first chemistry includes closed bonds only in one-dimension or a three-dimensional bonding network.

9. (canceled)

10. The composition of claim 1, wherein the second chemistry comprises one of a group IV semiconductor, a group III-V semiconductor, and a metal.

11. (canceled)

12. (canceled)

13. The composition of claim 1, wherein the first region is an isolated stripe.

14. The composition of claim 1, wherein the first region has an irregular shape.

15. The composition of claim 14, wherein the irregular shape comprises a T-junction, a jog, or an angle.

16. The composition of claim 1, wherein the block copolymer material consists essentially of a block copolymer.

17. The composition of claim 1, wherein horizontal domains of the block copolymer material are over the background.

18. The composition of claim 1, wherein the domains are less than 10 nm wide.

19. The composition of claim 1, wherein the chemical contrast pattern comprises stripes that are at least 80 nm wide.

20. The composition of claim 1, wherein the block copolymer material comprises an A-B diblock copolymer or A-B-A triblock copolymer.

21.-36. (canceled)
